(19) United States
(12) Patent Application Publication
(10) Pub. No.: US 2008/0012105 A1
(43) Pub. Date: Jan. 17, 2008

(54) Chip adapter

(75) Inventor: Sheng-Fu Chen, Taipei City (TW)

Correspondence Address: BACON & THOMAS, PLLC, 625 SLATERS LANE, FOURTH FLOOR, ALEXANDRIA, VA, 22314, US

(73) Assignee: WIESON TECHNOLOGIES CO., LTD., Hsi-Chih City (TW)

(21) Appl. No.: 11/483,530

(22) Filed: Jul. 11, 2006

(51) Int. Cl. H01L 23/02

(52) U.S. Cl. 257/678

(57) ABSTRACT

A chip adapter includes an adapter body, which has an accommodation top open chamber that accommodates a chip, a plurality of conducting elements respectively mounted in a bottom side in the accommodation top open chamber and bonded to a motherboard for the contact of respective contacts of the accommodated chip, a hook disposed at one side, and two pivot holes at an opposite side, and a M-shaped metal spring rod, which has two coupling end tips respectively pivoted to the pivot holes of the adapter body, a middle retaining portion for fastening to the hook of the adapter body, and two pressure arms connected between the coupling end tips and the middle retaining portion for imparting a downward pressure to the accommodated chip to hold the chip in position.

### BACKGROUND OF THE INVENTION

1. Field of the Invention

The present invention relates to a chip adapter for holding a chip and electrically connecting the chip to a motherboard and more particularly, to such a chip that fits any of a variety of chips of same size but different specifications and that allows quick replacement of the installed chip.

2. Description of the Related Art

Following fast development of electronic industry and the application of electronic technology, a variety of high-tech electronic products have been continuously created and used in our daily life to help handling different works and to improve outer living quality. Electronic products commonly use different IC (integrated circuit) chips to handle, analyze, and/or process data. More particularly, computer, communication and consumer electronic products have become more and more popular nowadays.

A motherboard generally has many IC chips bonded thereto. When upgrading a computer, the related IC chips may have to be replaced. Further, chips of same size may have different specifications, for example, 4 MB, 8 MB, 16 MB or 32 MB for different performance requirements. However, the IC chips of a computer have been fixedly bonded to the motherboard before sending out of the factory to the distributor. Therefore, a computer user cannot freely change or upgrade the IC chips. When one IC chip failed, the user cannot replace the damaged IC chip conveniently. In this case, the user may have to replace the whole motherboard or to send the computer to the repair center for repair. Handling the problem in this way costs a lot.

In the last four decades, semiconductor technology has been rapidly developed, and the device pitch in a single chip has been greatly reduced. Therefore, chip size has been greatly reduced. Following the requirement for mall-sized designs, the manufacturing precision becomes more and more critical, and the industry faces a great challenge in yield rate. In consequence, manufacturers encounter many maintenance and repair problems. Therefore, people skilled in the art are trying hard to find new methods that allow quick installation and replacement of chips.

### SUMMARY OF THE INVENTION

The present invention has been accomplished under the circumstances in view. It is main object of the present invention to provide a chip adapter, which fits same size chips of different specifications. It is another object of the present invention to provide a chip adapter, which allows quick replacement of the installed chip.

To achieve this and other objects of the present invention, the chip adapter comprises an adapter body and a M-shaped metal spring rod. The adapter body has an accommodation top open chamber that accommodates a chip, a plurality of conducting elements respectively mounted in a bottom side in the accommodation top open chamber and bonded to a motherboard for the contact of respective contacts of the accommodated chip, a hook disposed at one side, and two pivot holes at an opposite side. The M-shaped metal spring rod has two coupling end tips respectively pivoted to the pivot holes of the adapter body, a middle retaining portion for fastening to the hook of the adapter body, and two pressure arms connected between the coupling end tips and the middle retaining portion for imparting a downward pressure to the accommodated chip to hold the chip in position.

### BRIEF DESCRIPTION OF THE DRAWINGS

FIG. 1 is an oblique elevational view of a chip adapter according to the present invention.

FIG. 2 is another oblique elevational view of the chip adapter according to the present invention when viewed from another angle.

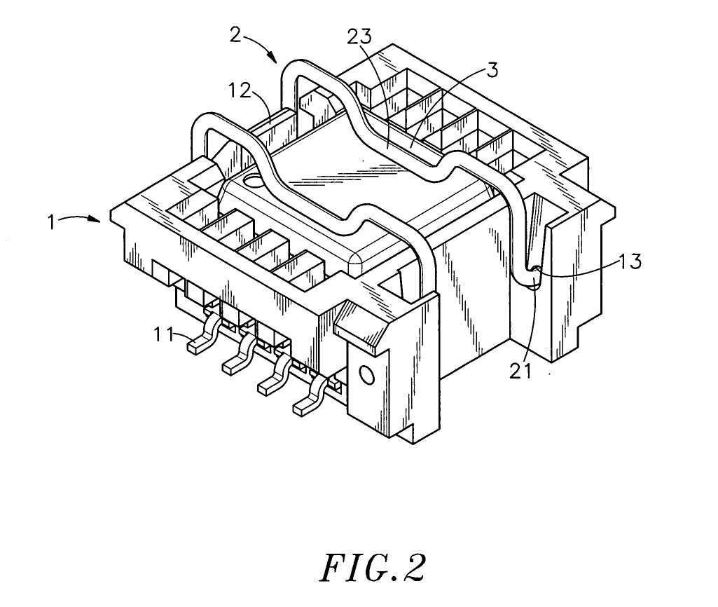

FIG. 3 is an exploded view of the chip adapter according to the present invention.

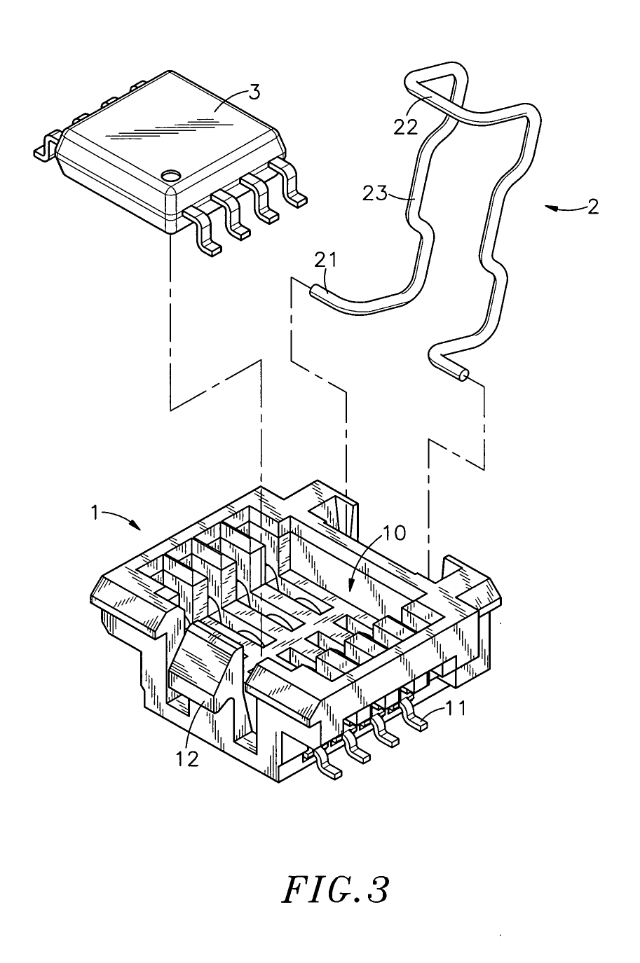

FIG. 4 is a schematic side sectional view showing the installation of the chip adapter in a motherboard according to the present invention (I).

FIG. 5 is a schematic side sectional view showing the installation of the chip adapter in a motherboard according to the present invention (II).

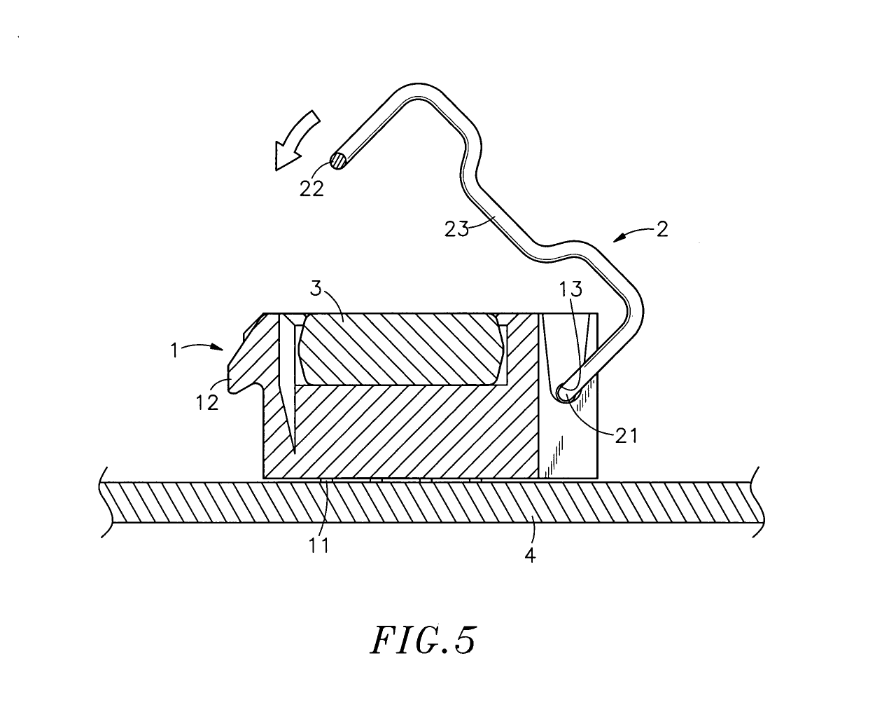

FIG. 6 is a schematic side sectional view showing the installation of the chip adapter in a motherboard according to the present invention (III).

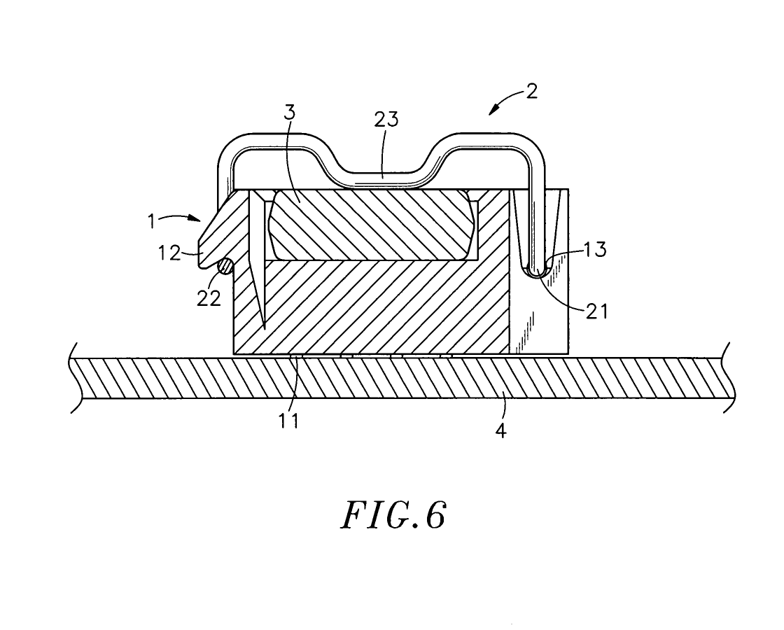

### DETAILED DESCRIPTION OF THE INVENTION

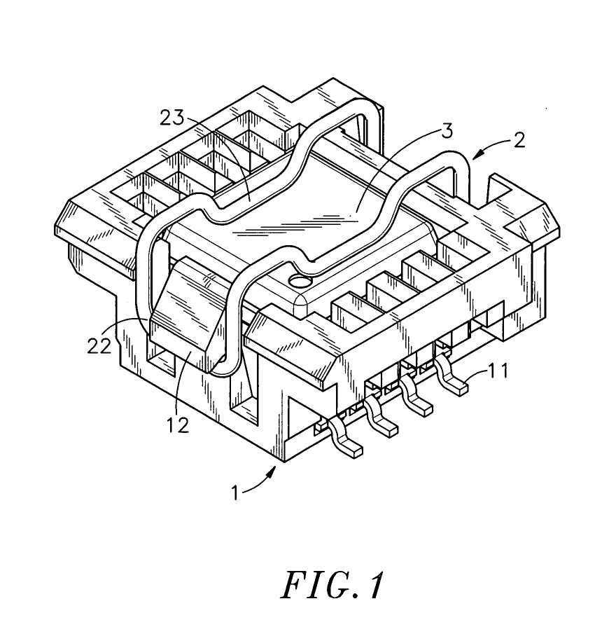

Referring to FIGS. 1˜3, a chip adapter in accordance with the present invention is shown comprised of an adapter body 1 and a fastening spring member 2.

The adapter body 1 is a hollow frame having an accommodation top open chamber 10 for accommodating a chip 3, a plurality of conducting elements 11 respectively fastened to the bottom side inside the accommodation top open chamber 10 and extending to the outside of the adapter body 1 for bonding to a motherboard 4, a hook 12 suspending at one side, and pivot holes 13 transversely aligned at an opposite side.

The fastening spring member 2 is a substantially M-shaped metal spring rod, having coupling end tips 21 respectively and pivotally coupled to the pivot holes 13 of the adapter body 1, a middle retaining portion 22 for fastening to the hook 12 of the adapter body 1, and two pressure arms 23 respectively connected between two distal ends of the middle retaining portion 22 and the coupling end tips 21.

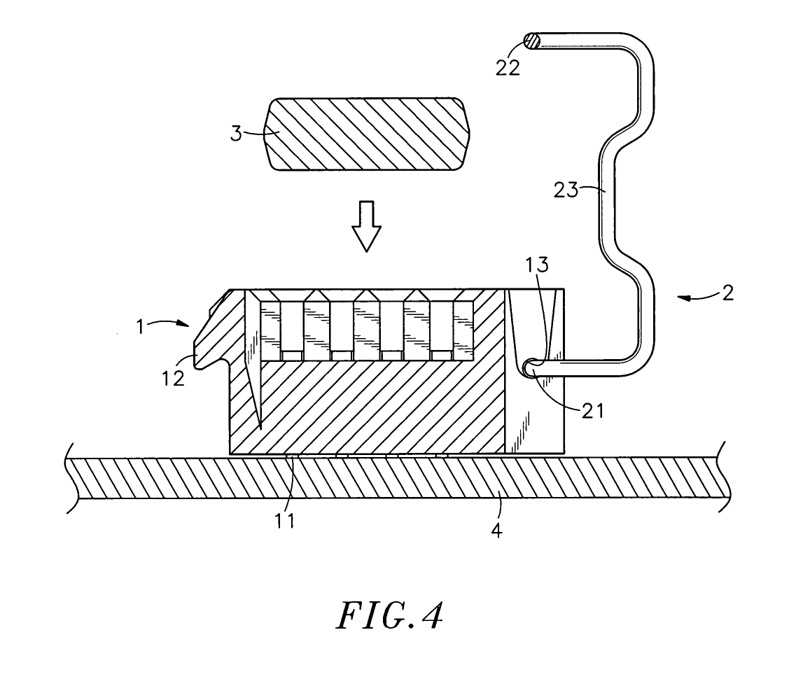

Referring to FIGS. 4˜6, before use of the present invention, the two coupling end tips 21 are respectively and pivotally coupled to the pivot holes 13 of the adapter body 1. When in use, the conducting elements 11 of the adapter body 1 are respectively bonded to the motherboard 4, and then the chip 3 is inserted into the accommodation top open chamber 10 of the adapter body 1 to force respective contacts of the chip 3 into contact with the conducting elements 11 of the adapter body 1 respectively, and then the fastening spring member 2 is turned toward the hook 12 to force the middle retaining portion 22 into engagement with the hook 12. At this time, the pressure arms 23 of the fastening spring member 2 are pressed on the top side of the chip 3, holding the chip 3 firmly in position.

When wishing to remove the chip 3 from the adapter body 1, push the hook 12 inwards toward the inside of the accommodation top open chamber 10 to disengage the middle retaining portion 22, and then turn the fastening spring member 2 outwards from the chip 3, and then take the chip 3 out of the accommodation top open chamber 10.

Further, the accommodation top open chamber 10 is designed subject to the size and pin arrangement of the chip 3. The chip 3 can be of DIP package type, TSOP package type or BGA package type. The conducting elements 11 can be plug pins, SMT pins, metal contacts, balls of solder for BGA packaging or any of a variety of other equivalent structures that effectively and electrically connecting the respective contacts 31 of the chip 3 to respective contacts of the motherboard 4.

As indicated above, the invention has the following technical features:

1. The fastening spring member 2 imparts a downward pressure to the chip 3 to hold the chip 3 positively in the accommodation top open chamber 10 inside the adapter body 1, keeping the contacts of the chip 3 in positive contact with the conducting elements 11, thereby achieving quick replacement, easy and labor-saving installation, and positive chip positioning.

2. The holder body 1 is bonded to the motherboard 4 to fit any of a variety of chips 3 that have different specifications but in the same size (the specification of the chip can be 4 MB, 16 MB or 32 MB). By means of the fastening spring member 2, the selected chip 3 is positively positioned in the accommodation top open chamber 10 of the adapter body 1. When wishing to change or upgrade the chip 3, the user can conveniently remove the chip 3 from the adapter body 1 without performing a disbanding process or using any tools.

A prototype of chip adapter has been constructed with the features of FIGS. 1˜6. The chip functions smoothly to provide all of the features discussed earlier.

Although a particular embodiment of the invention has been described in detail for purposes of illustration, various modifications and enhancements may be made without departing from the spirit and scope of the invention. Alternatively, the housing can be composed of a number of plastic parts. Accordingly, the invention is not to be limited except as by the appended claims.

What is claimed is:

1. A chip adapter comprising an adapter body, said adapter body having an accommodation top open chamber adapted to accommodate a chip, a plurality of conducting elements respectively mounted in a bottom side in said accommodation top open chamber and bonded to respective contact of a motherboard for the contact of respective contacts of the chip that is accommodated in said accommodation top open chamber, a hook disposed at a first side thereof, two pivot holes disposed at a second side thereof opposite to said first side, and fastening means adapted to hold said accommodated chip in said accommodation top open chamber positively in position, wherein said fastening means is a metal spring member having two coupling end tips disposed at one side and respectively coupled to said pivot holes of said adapter body and a retaining portion disposed at an opposite side for fastening to said hook of said adapter body, and at least one pressure arm connected between said coupling end tips and said retaining portion for imparting a downward pressure to said accommodated chip in said accommodation top open chamber.

2. The chip adapter as claimed in claim 1, wherein said conducting elements are metal plug pins.

3. The chip adapter as claimed in claim 1, wherein said conducting elements are SMT pins.

4. The chip adapter as claimed in claim 1, wherein said conducting elements are metal contacts.

5. The chip adapter as claimed in claim 1, wherein said conducting elements are balls of solder for BGA packaging.

6. The chip adapter as claimed in claim 1, wherein said metal spring member of said fastening means is a M-shaped metal spring rod.
